(19) United States
(12) Patent Application Publication
(10) Pub. No.: US 2012/0235114 A1
(43) Pub. Date: Sep. 20, 2012

(54) LIGHT EMITTING CHIP

(75) Inventor: JIAN-SHIHN TSANG, Tu-Cheng (TW)

(73) Assignee: HON HAI PRECISION INDUSTRY CO., LTD., Tu-Cheng (TW)

(21) Appl. No.: 13/235,510

(22) Filed: Sep. 19, 2011

(30) Foreign Application Priority Data
Mar. 16, 2011 (TW) 100109028

(51) Int. Cl. H01L 33/06

(52) U.S. Cl. 257/13; 257/E33.008

(57) ABSTRACT

A light emitting chip includes a substrate, a first reflective layer formed on the substrate, a lighting structure formed on the first reflective layer, and a first electrode formed between the first reflective layer and the substrate. The lighting structure includes a first semiconductor layer, an active layer and a second semiconductor layer. A receiving groove is defined in the lighting structure and extends from the first reflective layer to the first semiconductor layer. The receiving groove has a second reflective layer formed on an interior sidewall thereof. The first electrode includes a base and a connecting section extending upwardly from the base. The connecting section is surrounded by the second reflective layer and electrically connects with the first semiconductor layer. The first and second reflective layers each are electrically insulating.

### 1. TECHNICAL FIELD

The disclosure generally relates to a light emitting chip.

### 2. DESCRIPTION OF RELATED ART

In recent years, due to excellent light quality and high luminous efficiency, light emitting diodes (LEDs) have increasingly been used as substitutes for incandescent bulbs, compact fluorescent lamps and fluorescent tubes as light sources of illumination devices.

The LED generally includes a light emitting chip. Electrodes are formed on the light emitting chip to provide power for the light emitting chip. However, the electrodes are generally formed on an upper surface of the light emitting chip, whereby the electrodes block light from travelling to an external environment. The light extraction efficiency of the light emitting chip is then decreased with the increase of the electrode areas.

Therefore, a light emitting chip is desired to overcome the above described shortcomings.

### BRIEF DESCRIPTION OF THE DRAWINGS

Many aspects of the disclosure can be better understood with reference to the following drawings. The components in the drawings are not necessarily drawn to scale, the emphasis instead being placed upon clearly illustrating the principles of the disclosure. Moreover, in the drawings, like reference numerals designate corresponding parts throughout the several views.

FIG. 1 shows a light emitting chip in accordance with a first embodiment of the present disclosure.

FIG. 2 shows a light emitting chip in accordance with a second embodiment of the present disclosure.

### DETAILED DESCRIPTION

Embodiments of a light emitting chip will now be described in detail below and with reference to the drawings.

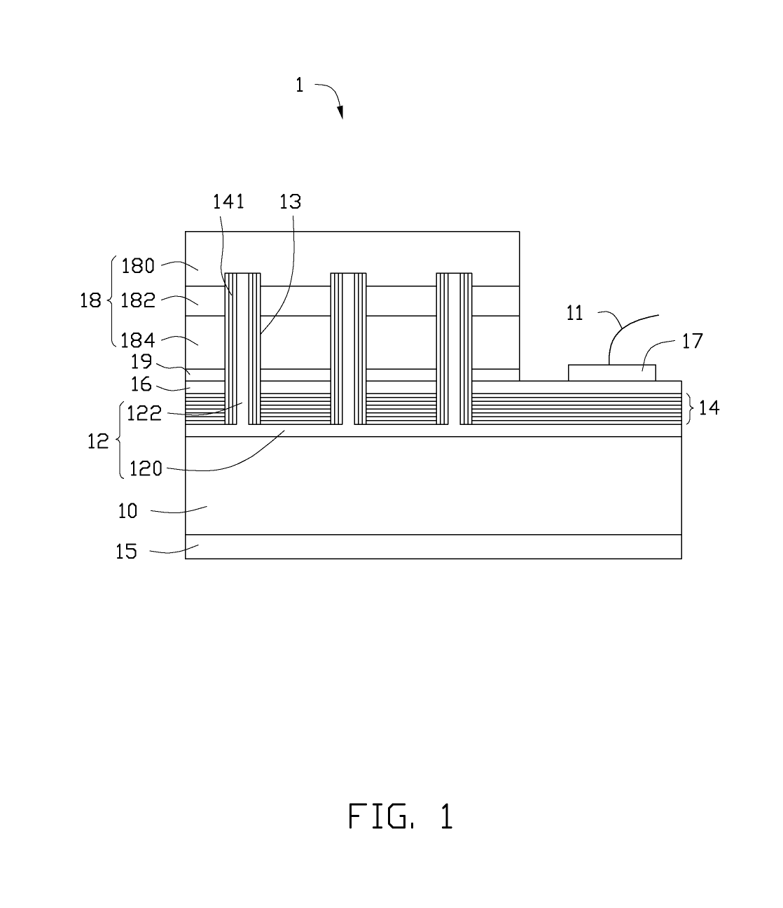

Referring to FIG. 1, a light emitting chip 1 in accordance with a first embodiment includes a substrate 10, a first electrode 12 formed on the substrate 10, a first reflective layer 14 formed on the first electrode 12, a transparent conductive layer 16 overlapped on the first reflective layer 14, a second electrode 17 formed on the transparent conductive layer 16, a lighting structure 18 and a (Ohmic) contact layer 19 formed between the lighting structure 18 and the transparent conductive layer 16.

The lighting structure 18 includes a first semiconductor layer 180, an active layer 182 and a second semiconductor layer 184. In this embodiment, the first semiconductor layer 180 is an n-type AlInGaN layer, the second semiconductor layer 184 is a p-type AlInGaN layer, and the active layer 182 is an InGaN/GaN multiple quantum well (MQW). The lighting structure 18 is firstly grown on a temporary substrate (not shown), and then separated from the temporary substrate by laser lift-off, chemical etching or physical etching. A bottom surface of the second semiconductor layer 184 is connected with the transparent conductive layer 16 through the (Ohmic) contact layer 19. The (Ohmic) contact layer 19 is made of heavy doping p-type In_{1-x-y}AlₓGa_{y}N, p-type In_{1-x-y}AlₓGa_{y}N with supper lattice structure, or p-doping inversion layer, therefore enhancing ohmic contact between the second semiconductor layer 184 and the transparent conductive layer 16. The transparent conductive layer 16 can be made of indium tin oxide (ITO), indium zinc oxide (IZO), zinc oxide (ZnO), magnesium oxide (MgO) or indium gallium zinc oxide (IGZO), thereby spreading current uniformly into the second semiconductor layer 184, and achieving a uniform light distribution of the light emitting chip 1.

The first reflective layer 14 is formed on the first electrode 12, and made of electrically insulating materials with high reflectivity. The light from the active layer 182 is reflected by the first reflective layer 14 and travels to an external environment, therefore improving light extraction efficiency of the light emitting chip 1. In this embodiment, the first reflective layer 14 is a distributed bragg reflector (DBR), which can reflect the light with a wavelength ranging from 440 nm to 470 nm. Materials of the first reflective layer 14 can be selected from a group consisting of SiO₂, TiO₂, Ta₂O₅, SiNₓ, TiNₓ and TaNₓ. In this embodiment, the first reflective layer 14 includes a plurality of SiO₂ films and TiO₂ films arranged alternately along a height direction of the light emitting chip 1.

The first electrode 12 is formed on the substrate 10. Materials of the first electrode 12 are selected from a group consisting of Cr, Ti, Ni, Pt, Al, Au, Ag, Cu, W and alloys thereof. The first electrode 12 includes a base 120 formed on the substrate 10 and a plurality of connecting sections 122 extending upwardly from the base 120. The base 120 can be circular, annular, strip-shaped or grid-shaped. In this embodiment, the base 120 is strip-shaped. The light emitting chip 1 defines a plurality of receiving grooves 13 extending from an upper surface of the substrate 10 to an interior of the first semiconductor layer 180. The connecting sections 122 are positioned inside the receiving grooves 13, respectively. A second reflective layer 141 is formed in the receiving groove 13 and surrounds the connecting section 122. The second reflective layer 141 is also made of electrically insulating materials to isolate the connecting section 122 from the active layer 182 and the second semiconductor layer 184. Similar to the first reflective layer 14, the second reflective layer 141 is also a distributed bragg reflector (DBR), which can reflect the light with a wavelength ranging from 440 nm to 470 nm. Materials of the second reflective layer 141 can be selected from a group consisting of SiO₂, TiO₂, Ta₂O₅, SiNₓ, TiNₓ and TaNₓ. In this embodiment, the second reflective layer 141 includes a plurality of SiO₂ films and TiO₂ films arranged alternately along a lateral direction of the light emitting chip 1. The second reflective layer 141 and the first reflective layer 14 can be deposited at the same time by CVD (Chemical Vapor Deposition), PVD (Physical Vapor Deposition), Electron beam evaporation or sputtering deposition.

The substrate 10 is electrically conductive, which is made of metallic or semiconductor materials. The materials of the substrate 10 can be selected from a group consisting of Si, SiC, GaN, ZnO and Al₂O₃. A soldering pad 15 is formed on a bottom surface of the substrate 10, opposite to the first electrode 12. Therefore, the first semiconductor layer 180 is capable of being connected to an external power source through the first electrode 12, the substrate 10 and the soldering pad 15.

The lighting structure 18 is etched to expose a part of the transparent conductive layer 16. The second electrode 17 is formed on the exposed transparent conductive layer 16 and connected with external power source through a metallic wire 11. Therefore, the second semiconductor layer 184 can be connected to the external power source through the contact layer 19, the transparent conductive layer 16 and the second electrode 17. Since the first and second electrodes 12, 16 are not formed on the first semiconductor layer 180 of the light emitting chip, light of the active layer 182 can easily travel to the external environment, and accordingly, lighting extraction efficiency of the present light emitting chip 1 is high.

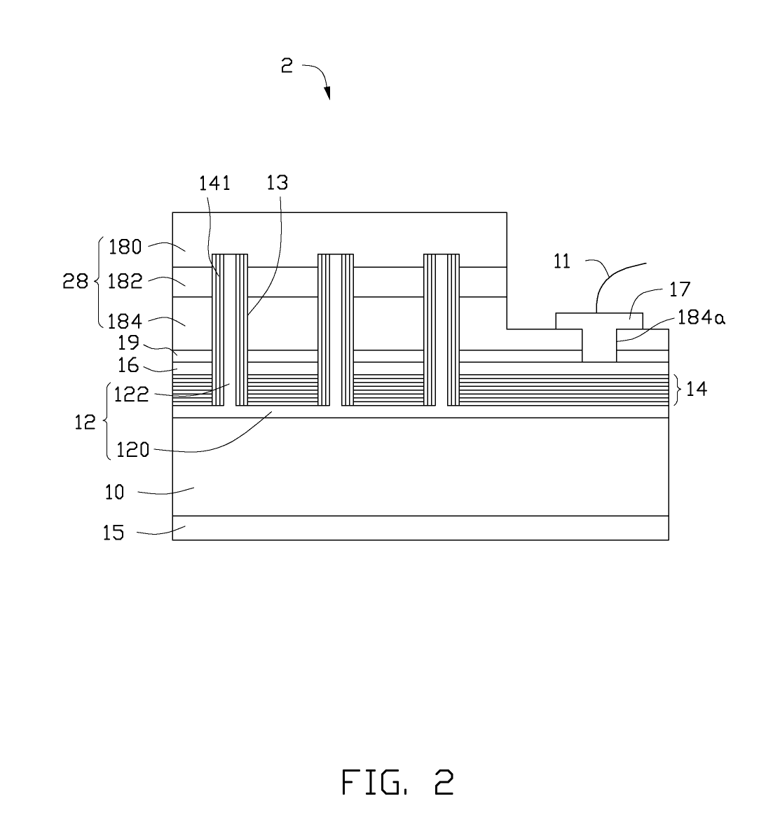

Referring to FIG. 2, a light emitting chip 2 in accordance with a second embodiment is provided. Different from the first embodiment, the lighting structure 28 is etched and a part of the second semiconductor layer 184 is exposed. A through hole 184a is formed in the exposed part of the second semiconductor layer 184, extending from an upper surface of the exposed part of the second semiconductor layer 184 to the transparent conductive layer 16. The second electrode 17 is formed on the second semiconductor layer 184 and penetrates through the through hole 184a to contact the transparent conductive layer 16.

In the light emitting chip described above, the first electrode 12 is buried inside the light emitting chip, rather than formed on the upper surface of the first semiconductor layer 180. Therefore, light travelling towards the external environment from the first semiconductor layer 180 will not be blocked by the first electrode 12, therefore improving light extraction efficiency of the light emitting chip.

Besides, the first reflective layer 14 and the second reflective layer 141 can be made of thermally conductive materials to improve heat dissipation efficiency of the light emitting chip 1, 2.

It is believed that the present embodiments and their advantages will be understood from the foregoing description, and it will be apparent that various changes may be made thereto without departing from the spirit and scope of the disclosure or sacrificing all of its material advantages, the examples hereinbefore described merely being preferred or exemplary embodiments of the disclosure.

What is claimed is:

1. A light emitting chip, comprising:
a substrate;
a first reflective layer formed on the substrate, the first reflective layer being made of electrically insulating material;
a lighting structure formed on the first reflective layer, the lighting structure comprising a first semiconductor layer, a second semiconductor layer and an active layer formed between the first semiconductor layer and the second semiconductor layer, the second semiconductor layer being adjacent to the first reflective layer;
a receiving groove extending from a bottom surface of the first reflective layer to the first semiconductor layer;
a second reflective layer made of insulating material being formed in the receiving groove and attached on a sidewall surrounding the receiving groove; and
a first electrode formed between the first reflective layer and the substrate, the first electrode comprising a base and a connecting section extending upwardly from the base, the connecting section being surrounded by the second reflective layer and electrically connected with the first semiconductor layer.

2. The light emitting chip of claim 1, wherein the substrate is made of metallic or semiconductor material.

3. The light emitting chip of claim 1, wherein a transparent conductive layer is formed between the second semiconductor layer and the first reflective layer, and the transparent conductive layer is made of ITO, IZO, ZnO, MgO or IGZO.

4. The light emitting chip of claim 3, wherein a contact layer is formed between the second semiconductor layer and the transparent conductive layer.

5. The light emitting chip of claim 4, wherein the contact layer is made of heavy doping p-type In_{1-x-y}AlₓGa_{y}N, p-type In_{1-x-y}AlₓGa_{y}N with supper lattice structure, or p-doping inversion layer.

6. The light emitting chip of claim 1, wherein the lighting structure is etched to expose a part of the transparent conductive layer, and a second electrode is formed on the exposed part of the transparent conductive layer.

7. The light emitting chip of claim 3, wherein the lighting structure is etched to expose a part of the second semiconductor layer, a through hole is formed in the exposed part of the second semiconductor layer and extends from an upper surface of the exposed part of the second semiconductor layer to the transparent conductive layer, and a second electrode is formed on the second semiconductor layer and penetrating through the through hole to contact the transparent conductive layer.

8. The light emitting chip of claim 1, wherein the first reflective layer and the second reflective layer each are a distributed bragg reflector.

9. The light emitting chip of claim 8, wherein a material of the first reflective layer and the second reflective layer is selected from a group consisting of SiO₂, TiO₂, Ta₂O₅, SiNₓ, TiNₓ and TaNₓ.

10. The light emitting chip of claim 9, wherein the first reflective layer comprises a plurality of SiO₂ films and TiO₂ films alternatively overlapping each other in a direction away from the substrate, and the second reflective layer comprises a plurality of SiO₂ films and TiO₂ films alternatively overlapping each other in a direction away from the interior sidewall of the receiving groove.

11. The light emitting chip of claim 1, wherein the first reflective layer and the second reflective layer reflect light with a wavelength ranging between 440 nm and 470 nm.

12. The light emitting chip of claim 1, wherein a material of the first electrode is selected from a group consisting of Cr, Ti, Ni, Pt, Al, Au, Ag, Cu, W and alloys thereof.

13. A light emitting chip, comprising:
a lighting structure comprising a first semiconductor layer, a second semiconductor layer and an active layer between the first semiconductor layer and the second semiconductor layer;
a hole extending through the second semiconductor layer and the active layer to reach the first semiconductor layer;
an electrode for connecting the light emitting chip to an external power source, the electrode being received in the hole, a gap being defined between an outer surface of the electrode and an inner surface of the lighting structure surrounding the hole, one end of the electrode being connected to the first semiconductor layer, and the other end of the electrode extending beyond the light structure for connecting with the external power source; and
an electrically insulating material filled in the gap for insulating the electrode from the second semiconductor layer and the active layer.

14. The light emitting chip of claim 13, wherein a part of a side of second semiconductor layer connected to the active layer is exposed, and another electrode is formed on the exposed part of the side of the second semiconductor layer for connecting the light emitting chip to the external power source.

15. The light emitting chip of claim 14, further comprising a contact layer attached to the second semiconductor layer and a conductive layer attached to the contact layer, the another electrode extending through the second semiconductor layer and the contact layer to connect with the conductive layer.

16. The light emitting chip of claim 13, further comprising a conductive layer attached to the second semiconductor layer, another electrode being formed on the conductive layer for connecting with the external power source.

17. The light emitting chip of claim 13, further comprising a contact layer attached to the second semiconductor layer and a transparent conductive layer attached to the contact layer, another electrode being formed on the transparent conductive layer for connecting with the external power source, the transparent conductive layer being made of one of ITO, IZO, ZnO, MgO and IGZO, the contact layer being one of heavy doping p-type In_{1-x-y}AlₓGa_{y}N, p-type In_{1-x-y}AlₓGa_{y}N with supper lattice structure, and p-doping inversion layer.

18. The light emitting chip of claim 17, further comprising an electrically insulating layer attached to the transparent conductive layer, and a conductive substrate, the another end of the electrode extending through the contact layer, the transparent conductive layer and the electrically insulating layer to connect with the conductive substrate.

19. The light emitting chip of claim 17, wherein the electrode further comprises a flat base formed on the another end thereof, an electrically insulating layer being formed between and interconnecting the flat base and the transparent conductive layer, a conductive substrate being attached to the flat base of the electrode.

20. The light emitting chip of claim 19, wherein the electrically insulating material and the electrically insulating layer each comprise a plurality of alternate SiO₂ films and TiO₂ films, and are capable of reflecting light with a wavelength ranging from 440 nm to 470 nm.
